(19) United States
(12) Patent Application Publication
(10) Pub. No.: US 2026/0304925 A1
(43) Pub. Date: Oct. 1, 2026

(54) NANOSHEET SEMICONDUCTOR DEVICE AND METHOD FOR MANUFACTURING THE SAME

(71) Applicant: TAIWAN SEMICONDUCTOR MANUFACTURING COMPANY, LTD., Hsinchu (TW)

(72) Inventors: Chung-Wei HSU, Hsinchu (TW); Lung-Kun CHU, Hsinchu (TW); Jia-Ni YU, Hsinchu (TW); Kuo-Cheng CHIANG, Hsinchu (TW); Chih-Hao WANG, Hsinchu (TW)

(73) Assignee: TAIWAN SEMICONDUCTOR MANUFACTURING COMPANY, LTD., Hsinchu (TW)

(21) Appl. No.: 19/092,202

(22) Filed: Mar. 27, 2025

(51) Int. Cl. H10D 84/83; H10D 84/01

(52) U.S. Cl. CPC H10D 84/8312; H10D 84/013; H10D 84/0147; H10D 84/8316; H10D 84/832

(57) ABSTRACT

A method for manufacturing a semiconductor device includes: forming a base semiconductor structure over a substrate, the base semiconductor structure including a first stack portion and a second stack portion spaced apart from each other by a recess, each of the first and second stack portions including sacrificial features and channel features alternately stacked over each other; replacing the sacrificial features with dielectric interposers; forming a source/drain region in the recess, the source/drain region extending into the base semiconductor structure, a thickness of the source/drain region being different from a width of the source/drain region in a cross-sectional view, the source/drain region including a source/drain feature having an n-type conductivity, the source/drain feature including seeding portions and an n-type epitaxial layer covering the seeding portions, the seeding portions containing a semiconductor material, the n-type epitaxial layer containing the semiconductor material and an n-type dopant.

### BACKGROUND

Integrated circuit (IC) chips have been applied in various electrical products, such as a central processing unit (CPU), a mobile phone, etc. An IC chip includes a plurality of semiconductor devices, such as nanosheet field-effect transistors (FETs), forksheet FETs, etc. Reduction in size of the semiconductor devices in the IC chip is advantageous for increasing economic benefit of the IC chip due to an increased functional density thereof (i.e., an increase in the number of the semiconductor devices per chip area). Nevertheless, electrical characteristics of the semiconductor devices may be adversely affected when the semiconductor devices are scaled down.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are flow diagrams illustrating a method for manufacturing a semiconductor device in accordance with some embodiments.

FIGS. 2A to 10C are schematic views illustrating some intermediate stages of the method as depicted in FIGS. 1A and 1B in accordance with some embodiments.

FIG. 11 is a schematic partially enlarged view illustrating the semiconductor device in accordance with some embodiments.

FIGS. 12 to 15 are schematic partially enlarged views each illustrating the semiconductor device in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “over,” “upper,” “lower,” “lowermost,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. It should be noted that the element(s) or feature(s) are exaggeratedly shown in the figures for the purposed of convenient illustration and are not in scale.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

The term “source/drain portion(s)” may refer to a source or a drain, individually or collectively dependent upon the context.

A semiconductor device including a plurality of nanosheet transistors (e.g., nanosheet field-effect transistors (FETs)) has wide applications due to superior device performance. A nanosheet FET structure may be a gate-all-around FET (GAAFET) structure. The nanosheet FET structure includes a semiconductor substrate, two source/drain regions, a plurality of channel features, a plurality of inner spacers, a metal gate, and other elements. The source/drain regions are disposed on the semiconductor substrate, the channel features are disposed on the semiconductor substrate and between the source/drain regions, and the inner spacers are laterally disposed at two opposite sides of a lower region of the metal gate. Some issues may occur with formation of the source/drain regions.

With respect to a p-type nanosheet FET structure, there may exist stacking faults (i.e., a lattice dislocation (an irregularity of atomic arrangement) occurred in the source/drain regions when at least one atom layer interrupts a normal periodic stacking of atoms) or a high defect density in the source/drain regions due to non-uniform merge of an epitaxial material of the source/drain regions during formation of the source/drain regions. The stacking faults or the high defect density may induce a weak strain (e.g., a compressive strain) to the channel features, resulting in a degradation to electrical performance of the p-type nanosheet FET structure. In this case, the non-uniform merge of the epitaxial material of the source/drain regions may occur due to the inner spacers being formed before formation of the source/drain regions of the p-type nanosheet FET structure.

With respect to an n-type nanosheet FET structure, an n-type dopant (e.g., phosphorous) in an epitaxial material (e.g., silicon phosphide) of the source/drain regions may diffuse into and remain in the channel features, resulting in reduced electron mobility and increased resistance of the channel features.

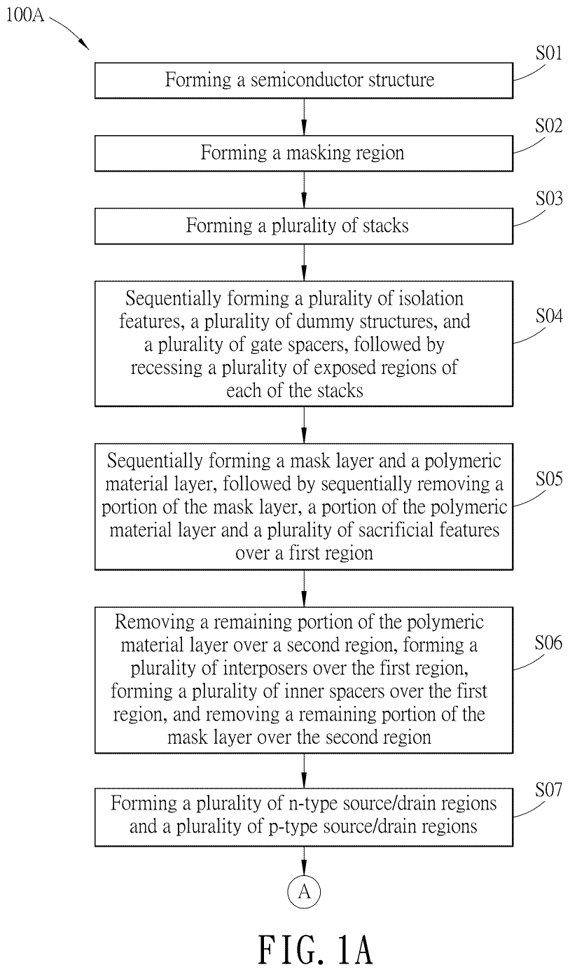

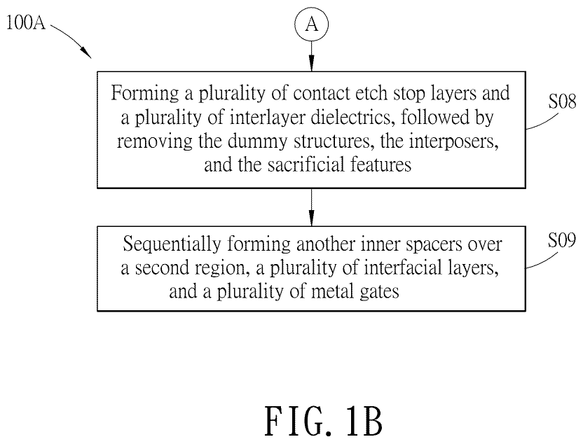

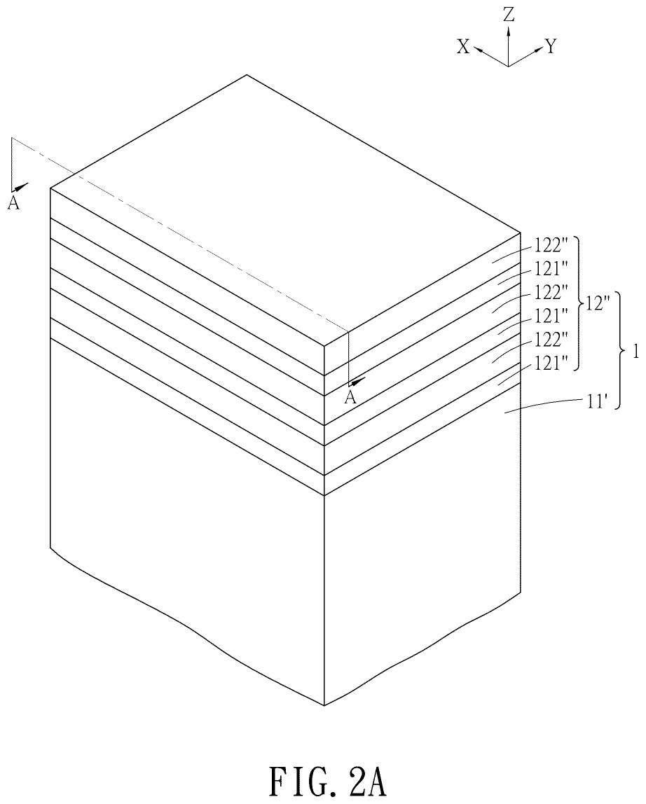

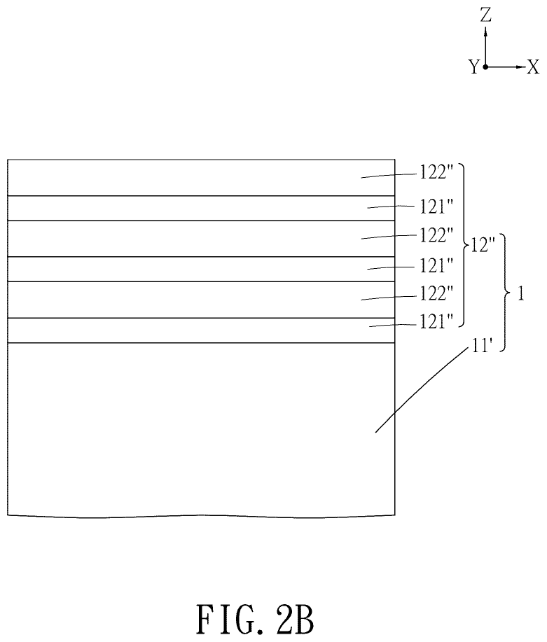

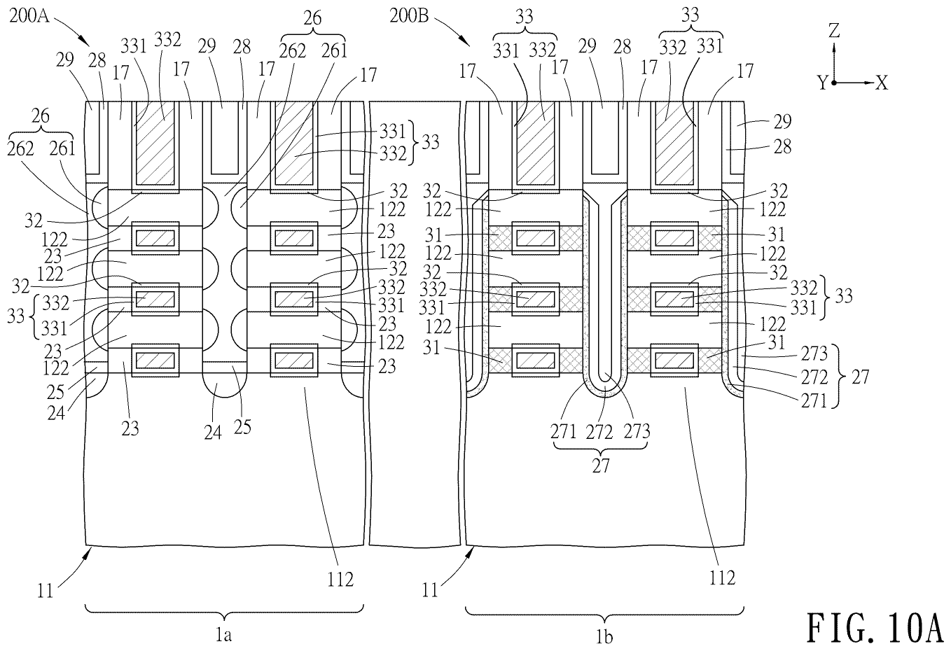

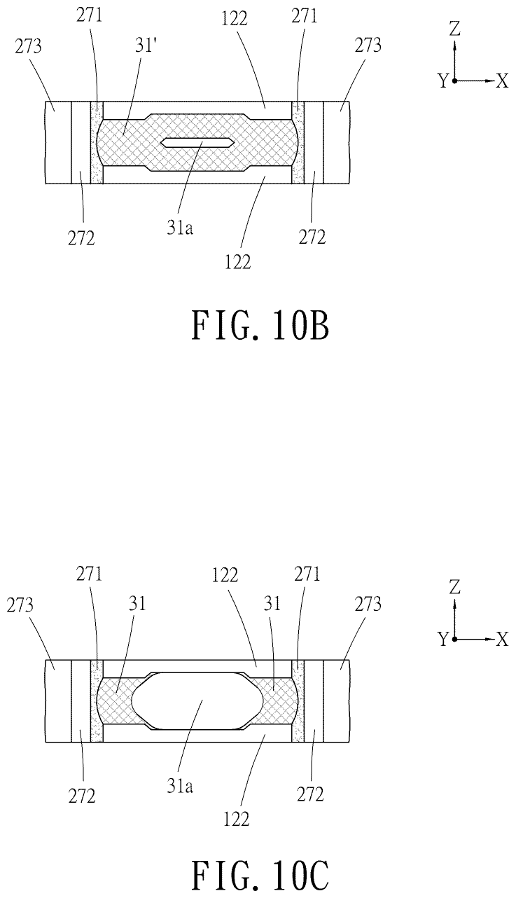

The present disclosure is directed to a semiconductor device and a method for manufacturing the same. FIGS. 1A and 1B are flow diagrams illustrating a method 100A for manufacturing a first semiconductor device 200A and a second semiconductor device 200B shown in FIG. 10A in accordance with some embodiments. FIGS. 2A to 9B illustrate schematic views of some intermediate stages of the method 100A. Some portions may be omitted in FIGS. 2A to 9B for the sake of brevity. Additional steps can be provided before, after or during the method 100A, and some of the steps described herein may be replaced by other steps or be eliminated.

Referring to FIG. 1A and the example illustrated in FIGS. 2A and 2B, the method 100A begins at step S01, where a semiconductor structure 1 is formed. FIG. 2B illustrates a cross-sectional view taken along line A-A of FIG. 2A. The semiconductor structure 1 includes a starting substrate 11′ and a material stack 12″.

The starting substrate 11′ may include, for example, but not limited to, an elemental semiconductor or a compound semiconductor. In some embodiments, the elemental semiconductor includes a single species of atoms, such as silicon or germanium in column XIV of the periodic table, and may be in a crystal form, a polycrystalline form, or an amorphous form. Other suitable elemental semiconductor materials are within the contemplated scope of the present disclosure. In some embodiments, the compound semiconductor includes two or more elements, and examples thereof may include, silicon carbide, gallium arsenide, gallium phosphide, indium phosphide, indium arsenide, indium antimonide, silicon germanium, gallium arsenide phosphide, aluminum indium arsenide, aluminum gallium arsenide, gallium indium arsenide, gallium indium phosphide, and gallium indium arsenide phosphide. Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the starting substrate 11′ may include a multilayer compound semiconductor structure. In some embodiments, the starting substrate 11′ may be a semiconductor on insulator (SOI) (e.g., silicon germanium on insulator (SGOI)). Generally, an SOI substrate includes a layer of a semiconductor material, such as epitaxial silicon, germanium, silicon germanium, or combinations thereof. The SOI substrate may be doped with a p-type dopant, for example, but not limited to, boron, aluminum, or gallium. Other suitable p-type dopant materials are within the contemplated scope of the present disclosure. Alternatively, the SOI substrate may be doped with an n-type dopant, for example, but not limited to, nitrogen, phosphorous, or arsenic. Other suitable n-type dopant materials are within the contemplated scope of the present disclosure.

The material stack 12″ is disposed on the starting substrate 11′ in a Z direction normal to the starting substrate 11′. The material stack 12″ includes a plurality of first material layers 121″ and a plurality of second material layers 122″ disposed to alternatingly stack with the first material layers 121″ in the Z direction. In some embodiments, the material stack 12″ is a stack of semiconductor materials. In some embodiments, the first material layers 121″ are made of a first semiconductor material, and the second material layers 122″ are made of a second semiconductor material that is different from the first semiconductor material, so that each layer of the second material layers 122″ has an etching rate different from that of each layer of the first material layers 121″. In some embodiments, the first semiconductor material may be silicon germanium, and the second semiconductor material may be silicon, so that each layer of the first material layers 121″ has an etching rate greater than that of each layer of the second material layers 122″. In some embodiments, the material stack 12″ may be formed on the starting substrate 11′ by a suitable deposition process (for example, but not limited to, chemical vapor deposition (CVD), atomic layer deposition (ALD), etc.), a suitable epitaxial growth process (for example, but not limited to, molecular beam epitaxy (MBE), selective epitaxial growth (SEG) process, etc.), or other suitable processes.

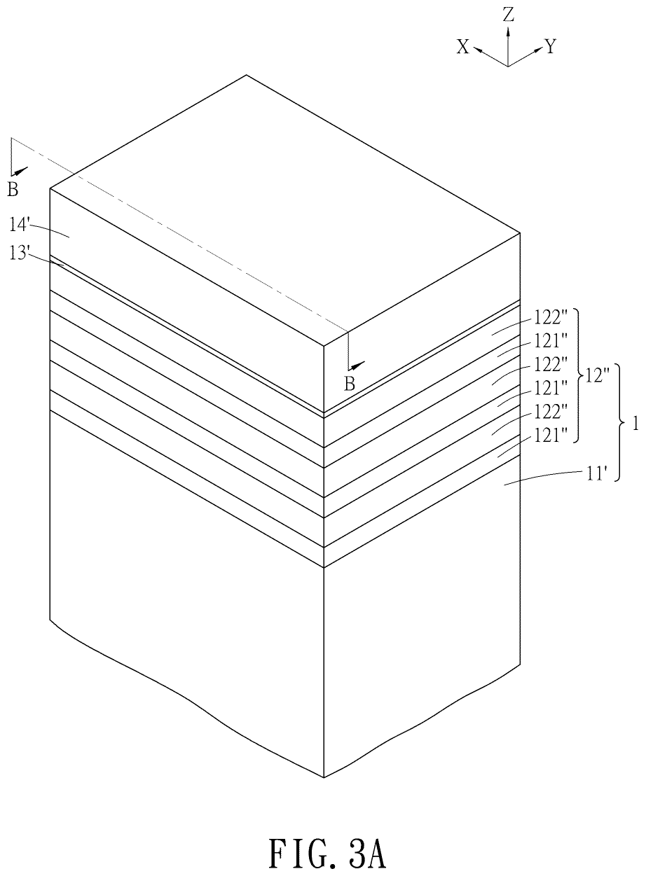

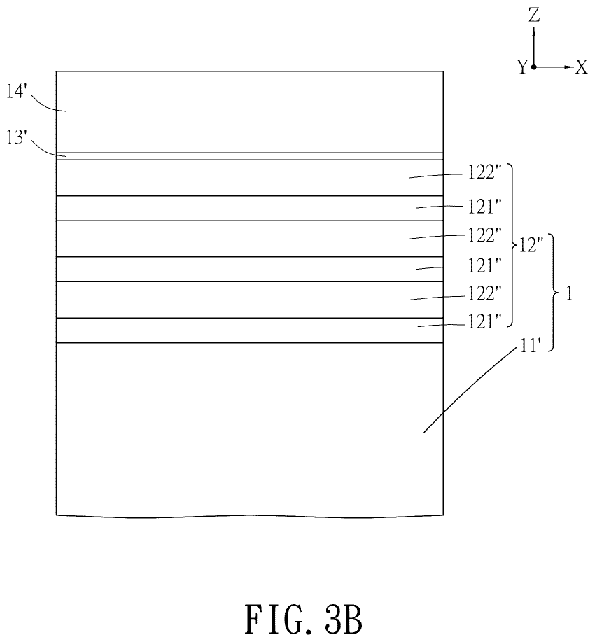

Referring to FIG. 1A and the example illustrated in FIGS. 3A and 3B, the method 100A then proceeds to step S02, where a masking region is formed on the semiconductor structure 1. FIG. 3B illustrates a cross-sectional view taken along line B-B of FIG. 3A. The masking region includes an oxide layer 13′ and a mask layer 14′ sequentially disposed on the semiconductor structure 1. In some embodiments, the oxide layer 13′ includes or is made of, for example, but not limited to, silicon oxide. Other suitable materials for forming the oxide layer 13′ are within the contemplated scope of the present disclosure. In some embodiments, the oxide layer 13′ may be formed by a suitable deposition process, for example, but not limited to, CVD or ALD. Other suitable deposition processes for forming the oxide layer 13′ are within the contemplated scope of the present disclosure. In some embodiments, the mask layer 14′ is made of a nitride-based material, which may include, for example, but not limited to, silicon nitride. Other suitable materials for forming the mask layer 14′ are within the contemplated scope of the present disclosure. In some embodiments, the mask layer 14′ is formed by a suitable deposition process, for example, but not limited to, CVD or ALD. Other suitable deposition processes for forming the mask layer 14′ are within the contemplated scope of the present disclosure.

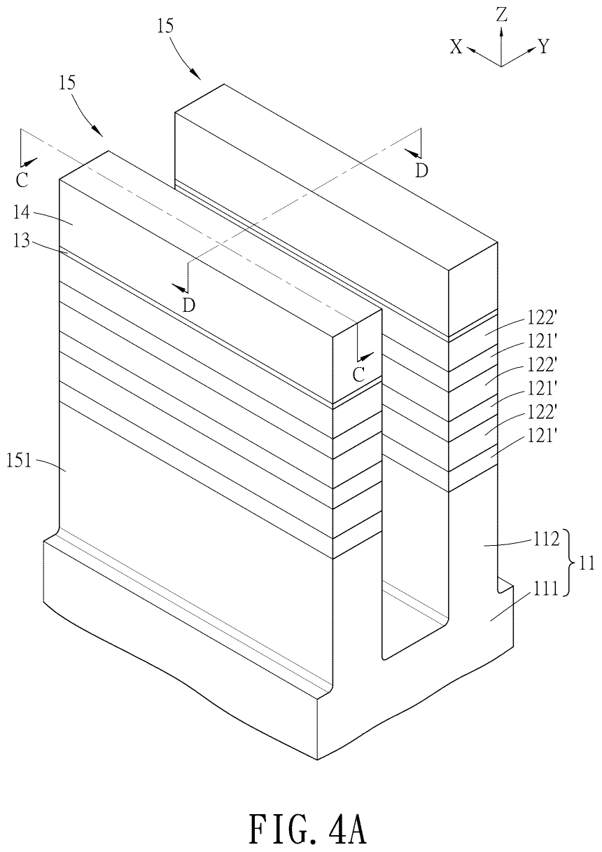

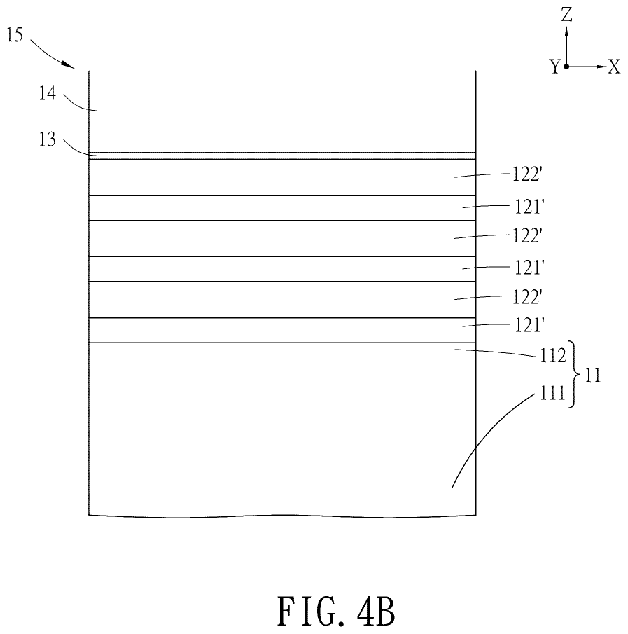

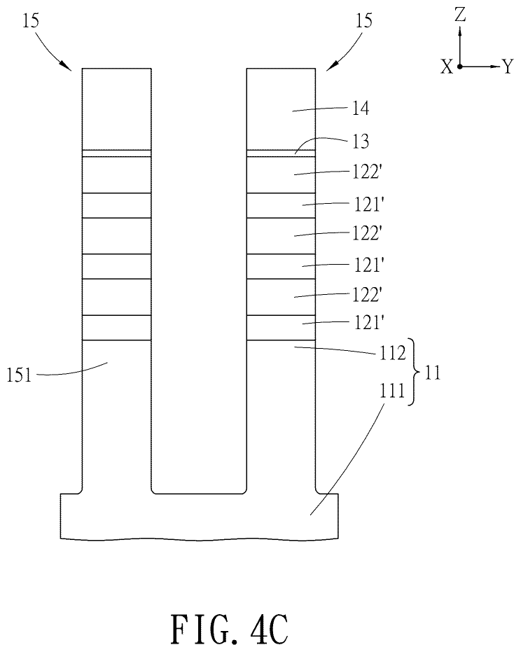

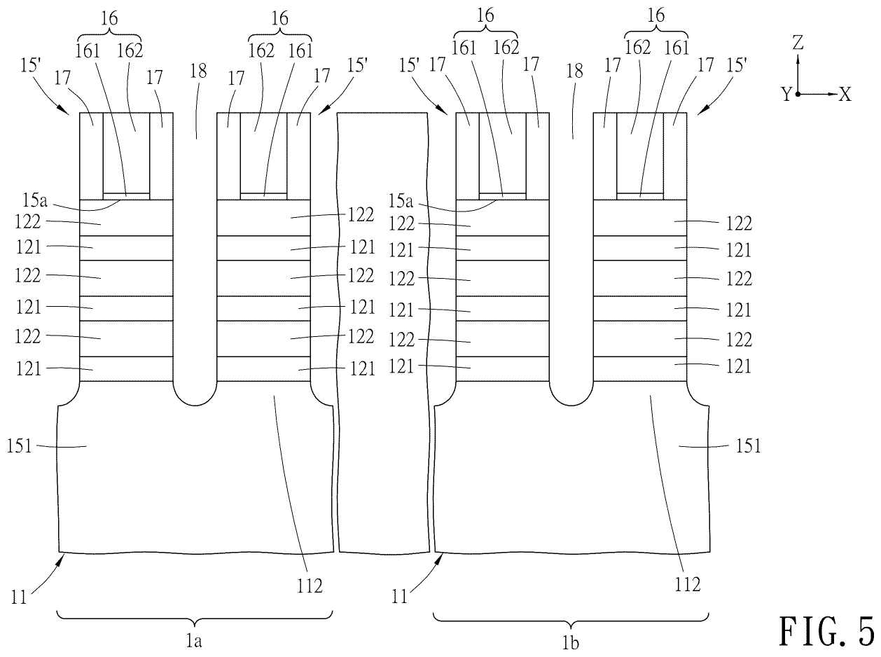

Referring to FIG. 1A and the example illustrated in FIGS. 4A to 4C, the method 100A then proceeds to step S03, where the semiconductor structure 1 is patterned to form a plurality of stacks 15. FIG. 4B illustrates a cross-sectional view taken along line C-C of FIG. 4A. FIG. 4C illustrates a cross-sectional view taken along line D-D of FIG. 4A. Step S03 may be performed by a photolithography process, which includes an etching process. The etching process may be, for example, but not limited to, an anisotropic etching process. A plurality of trenches are formed to penetrate the mask layer 14′, the oxide layer 13′, the material stack 12″ and an upper portion of the starting substrate 11′, and terminate at a lower portion of the starting substrate 11′. After this step, the starting substrate 11′ is formed into a patterned substrate 11, the first material layers 121″ are formed into a plurality of sacrificial layers 121′, the second material layers 122″ are formed into a plurality of channel layers 122′, the oxide layer 13′ is formed into a plurality of oxide layer portions 13, and the mask layer 14′ is formed into a plurality of mask layer portions 14. The stacks 15 are spaced apart from each other by the trenches in a Y direction and extend in an X direction. The X direction is transverse to the Z direction and parallel to a base 111 of the patterned substrate 11, and the Y direction is transverse to the X direction and the Z direction. In some embodiments, the X, Y, and Z directions are perpendicular to one another. Each of the stacks 15 includes a protrusion 151 disposed on the base 111 of the patterned substrate 11, corresponding ones of the sacrificial layers 121′, corresponding ones of the channel layers 122′ disposed to alternatingly stack with the corresponding ones of the sacrificial layers 121′ in the Z direction, a corresponding one of the oxide layer portions 13, and a corresponding one of the mask layer portions 14. In some embodiments, the protrusion 151 of each of the stacks 15 may be referred to as a corresponding one of protrusions 112 of the patterned substrate 11, which protrude upwardly from the base 111 of the patterned substrate 11. In some embodiments, an upper surface of each of the stacks 15 may have a plurality of covered regions 15a (see FIG. 5) and a plurality of exposed regions (not shown) that are alternated with one another in the X direction.

Referring to FIG. 1A and the example illustrated in FIG. 5, the method 100A then proceeds to step S04, where a plurality of isolation features (not shown), a plurality of dummy structures 16 and a plurality of gate spacers 17 are sequentially formed on the structure shown in FIGS. 4A to 4C, followed by recessing the exposed regions of each of the stacks 15.

In this step, an isolation layer for forming the isolation features is firstly formed on the structure shown in FIGS. 4A to 4C, followed by performing a suitable etching process, so as to obtain the isolation features. The isolation features are disposed on the base 111 of the patterned substrate 11. Each pair of the isolation features is located at two opposite sides of the protrusion 151 of a corresponding one of the stacks 15 so as to separate and isolate the stacks 15 from each other. The two opposite sides of the protrusion 151 are opposite to each other in the Y direction. In some embodiments, the isolation layer is made of an oxide-based material (e.g., silicon oxide), a nitride-based material (e.g., silicon nitride), or a combination thereof. Other suitable materials for forming the isolation layer are within the contemplated scope of the present disclosure. In some embodiments, the isolation layer is formed by a suitable deposition process, for example, but not limited to, CVD or physical vapor deposition (PVD). Other suitable deposition processes for forming the isolation layer are within the contemplated scope of the present disclosure. In some embodiments, each of the isolation features may be a portion of a shallow trench isolation (STI), a deep trench isolation (DTI), or other suitable isolation structures.

In some embodiments, the oxide layer portions 13 and the mask layer portions 14 are also removed during the etching process.

Secondly, the dummy structures 16 are formed on the isolation features and over the stacks 15, and are spaced apart from each other in the X direction. In some embodiments, each of the dummy structures 16 includes a dummy dielectric 161, a dummy gate 162, and a mask (not shown).

The dummy dielectric 161 of each of the dummy structures 16 is disposed on a corresponding one of the covered regions 15a of each of the stacks 15. The dummy dielectric 161 includes or is made of an oxide-based material (e.g., silicon oxide). Other suitable materials for forming the dummy dielectric 161 are within the contemplated scope of the present disclosure.

The dummy gate 162 is disposed on the dummy dielectric 161. The dummy gate 162 includes or is made of polysilicon. Other suitable materials for forming the dummy gate 162 are within the contemplated scope of the present disclosure.

The mask is disposed on the dummy gate 162 opposite to the dummy dielectric 161. In some embodiments, the mask includes or is made of a dielectric material, such as silicon nitride, silicon oxide, silicon oxynitride, or combinations thereof. Other suitable materials for forming the mask are within the contemplated scope of the present disclosure.

Next, each pair of the gate spacers 17 is respectively formed at two opposite sides of a corresponding one of the dummy structures 16 in the X direction. In some embodiments, each of the gate spacers 17 may be formed as a single layer structure or a multi-layered structure. The gate spacers 17 may be formed by depositing a spacer material layer on the dummy structures 16 and the exposed regions of the stacks 15 by a suitable deposition process, for example, but not limited to, CVD, ALD, or other suitable deposition processes, followed by conducting an anisotropic dry etching process until portions of the spacer material layer, which are respectively formed on the exposed regions of the stacks 15 and an upper surface of each of the dummy structures 16, are removed such that remaining portions of the spacer material layer serve as the gate spacers 17. The spacer material layer for forming the gate spacers 17 includes, for example, but not limited to, silicon oxide, silicon nitride, silicon oxynitride, silicon carbon nitride, silicon oxycarbonitride, or low-dielectric constant (k) materials. Other suitable materials for forming the spacer material layer are within the contemplated scope of the present disclosure.

Thereafter, the exposed regions of the stacks 15 are recessed by a suitable etching process, for example, but not limited to, a dry etching process, a wet etching process, other suitable etching processes, or combinations thereof, so as to form a plurality of source/drain recesses 18 that are spaced apart from one another in the X direction. After formation of the source/drain recesses 18, the stacks 15 are formed into a plurality of stack portions 15′. Each of the stack portions 15′ includes a plurality of sacrificial features 121 (formed from the sacrificial layers 121′) and a plurality of channel features 122 (formed from the channel layers 122′). Upper portions of the protrusions 151 are also patterned and recessed during formation of the source/drain recesses 18.

In some embodiments, the patterned substrate 11 may be divided into a first region 1a for the first semiconductor device 200A to be subsequently formed thereon, and a second region 1b for the second semiconductor device 200B to be subsequently formed thereon. In some embodiments, the first semiconductor device 200A serves as an n-type nanosheet FET device, and the second semiconductor device 200B serves as a p-type nanosheet FET device.

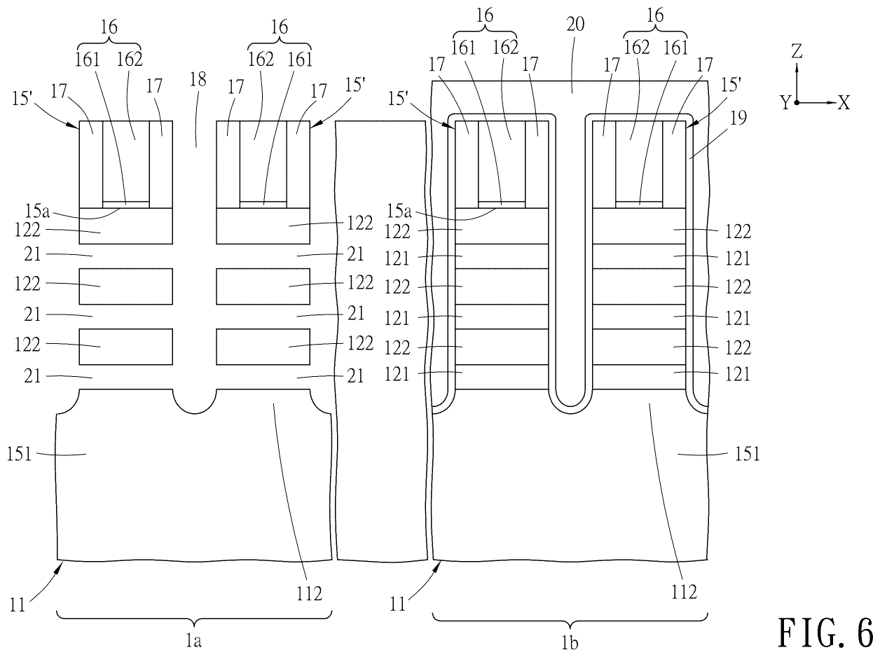

Referring to FIG. 1A and the example illustrated in FIG. 6, the method 100A then proceeds to step S05, where a mask layer 19 and a polymeric material layer 20 are sequentially formed on the structures over the first region 1a and the second region 1b, followed by removing a portion of the mask layer 19 and a portion of the polymeric material layer 20 over the first region 1a, and the sacrificial features 121 of the stack portions 15′ over the first region 1a (see FIG. 5).

In this step, firstly, the mask layer 19 is conformally formed to cover the structures over the first region 1a and the second region 1b. In some embodiments, the mask layer 19 includes or is made of, for example, but not limited to, aluminum oxide, aluminum nitride, or titanium nitride. Other suitable materials for forming the mask layer 19 are within the contemplated scope of the present disclosure. In some embodiments, the mask layer 19 is formed by a suitable deposition process, for example, but not limited to, ALD. Other suitable deposition processes for forming the mask layer 19 are within the contemplated scope of the present disclosure.

Secondly, the polymeric material layer 20 is formed on the structure obtained after formation of the mask layer 19. In some embodiments, the polymeric material layer 20 includes or is made of, for example, but not limited to, a bottom anti-reflective coating (BARC) material, such as a polyvinylphenol or a polystyrene. Other suitable materials for forming the polymeric material layer 20 are within the contemplated scope of the present disclosure. In some embodiments, the polymeric material layer 20 is formed by a suitable process, for example, but not limited to, spin-on coating. Other suitable processes for forming the polymeric material layer 20 are within the contemplated scope of the present disclosure.

Next, the portion of the polymeric material layer 20 and the portion of the mask layer 19 over the first region 1a are sequentially removed by a photolithography process, which includes two etching processes. In some embodiments, the portion of the polymeric material layer 20 may be removed by a suitable removal process, for example, but not limited to, a dry etching process, an ashing process, or a combination thereof. In some embodiments, the portion of the mask layer 19 may be removed by a suitable removal process, for example, but not limited to, a wet etching process. Other suitable removal processes for removing each of the portion of the polymeric material layer 20 and the portion of the mask layer 19 are within the contemplated scope of the present disclosure.

Thereafter, the sacrificial features 121 of the stack portions 15′ over the first region 1a are removed by a suitable etching process, for example, but not limited to, an isotropic etching process. Other suitable etching processes for removing the sacrificial features 121 of the stack portions 15′ over the first region 1a are within the contemplated scope of the present disclosure. After removal of the sacrificial features 121 of the stack portions 15′ over the first region 1a, a plurality of spaces 21 are formed. Each of lowermost ones of the spaces 21 is located between a corresponding one of the channel features 122 and a corresponding one of the protrusions 112 of the patterned substrate 11, and each of remaining ones of the spaces 21 is located between corresponding two adjacent ones of the channel features 122 over the first region 1a.

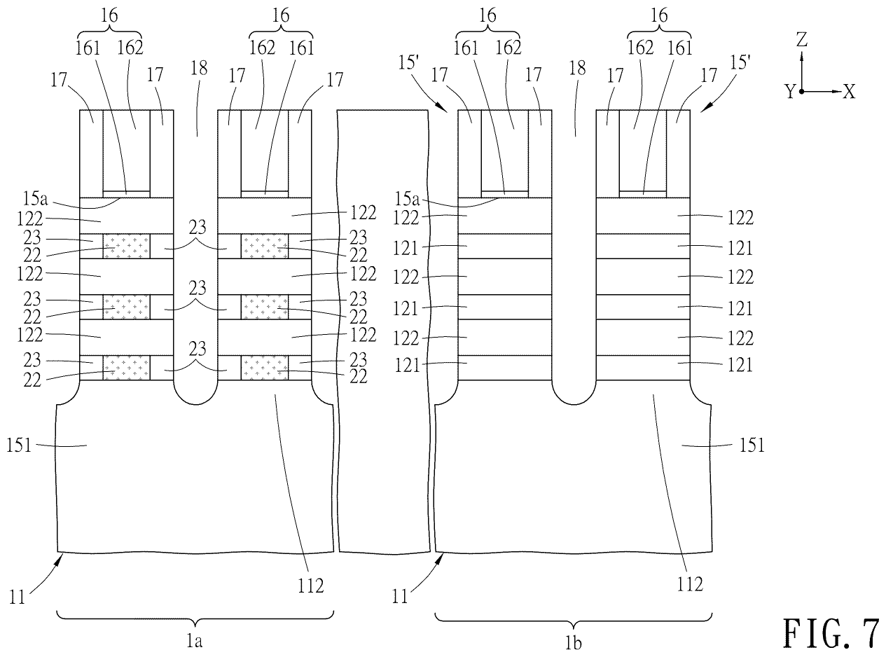

Referring to FIG. 1A and the example illustrated in FIG. 7, the method 100A then proceeds to step S06, where a remaining portion of the polymeric material layer 20 over the second region 1b is removed, and a plurality of interposers 22 and a plurality of inner spacers 23 are then formed in the spaces 21 over the first region 1a, followed by removing a remaining portion of the mask layer 19 over the second region 1b.

In this step, the remaining portion of the polymeric material layer 20 over the second region 1b is firstly removed by a suitable removal process, for example, but not limited to, a dry etching process, an ashing process, or a combination thereof. Other suitable removal processes for removing the remaining portion of the polymeric material layer 20 over the second region 1b are within the contemplated scope of the present disclosure.

Secondly, an oxide-based material layer (e.g., a silicon oxide layer) for forming the interposers 22 is formed on the structures (over the first region 1a and the second region 1b) obtained after removal of the remaining portion of the polymeric material layer 20 by a suitable deposition process, for example, but not limited to, CVD or ALD. Other suitable deposition processes for forming the oxide-based material layer are within the contemplated scope of the present disclosure.

Next, an isotropic etching process is performed to remove an excess portion of the oxide-based material layer, so as to obtain the interposers 22. Each of lowermost ones of the interposers 22 is located between a corresponding one of the channel features 122 and a corresponding one of the protrusions 112 of the patterned substrate 11, and each of remaining ones of the interposers 22 is located between corresponding two adjacent ones of the channel features 122. After the isotropic etching process is performed, a plurality of lateral recesses (not shown) are formed due to over-etching of the oxide-based material layer. In some embodiments, the lateral recesses are not formed.

Thereafter, a spacer material layer (not shown) for forming the inner spacers 23 is formed on the structure obtained after formation of the interposers 22 to fill the lateral recesses, followed by removing an excess portion of the spacer material layer, thereby obtaining the inner spacers 23 (i.e., remaining portions of the spacer material layer). In some embodiments, the spacer material layer includes, for example, but not limited to, silicon oxide, silicon nitride, silicon oxynitride, silicon carbonitride, silicon oxycarbonitride, silicon oxycarbide, silicon carbide, other suitable low-k dielectric materials, or combinations thereof. Other suitable materials for forming the spacer material layer are within the contemplated scope of the present disclosure. In some embodiments, the spacer material layer is formed by a suitable deposition process, for example, but not limited to, CVD or ALD. Other suitable deposition processes for forming the spacer material layer are within the contemplated scope of the present disclosure. In some embodiments, the excess portion of the spacer material layer may be removed by a suitable etching process, for example, but not limited to, a dry etching process, a wet etching process, or a combination thereof. In some embodiments, each pair of the inner spacers 23 laterally covers two opposite sides of a corresponding one of the interposers 22. In some embodiments, in which the lateral recesses are not formed, the inner spacers 23 may be omitted.

Then, the remaining portion of the mask layer 19 over the second region 1b is removed by a suitable removal process, for example, but not limited to, a wet etching process. Other suitable removal processes for removing the remaining portion of the mask layer 19 over the second region 1b are within the contemplated scope of the present disclosure.

It is noted that in this step, if the remaining portion of the polymeric material layer 20 over the second region 1b is not firstly removed (e.g., before the formation of the interposers 22 or formation of the inner spacers 23), contaminants may be produced from the remaining portion of the polymeric material layer 20 during the deposition processes and the etching processes for forming the interposers 22 and the inner spacers 23. In some embodiments, in which the remaining portion of the polymeric material layer 20 may remain intact after the deposition processes and the etching processes for forming the interposers 22 and the inner spacers 23, the remaining portion of the polymeric material layer 20 over the second region 1b may be removed after formation of the inner spacers 23 and before removal of the remaining portion of the mask layer 19 over the second region 1b.

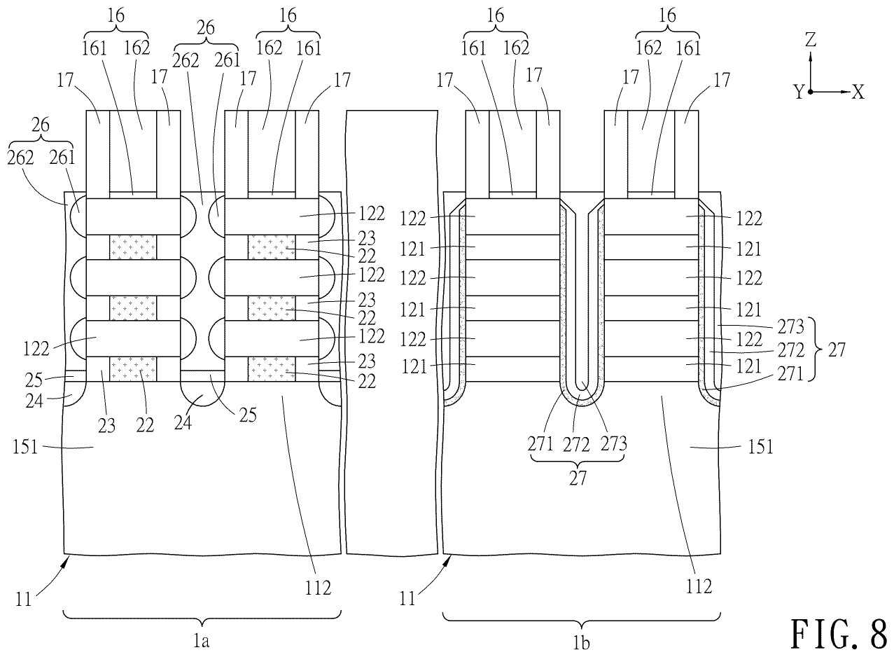

Referring to FIG. 1A and the examples illustrated in FIG. 8, the method 100A then proceeds to step S07, where a plurality of n-type source/drain regions and a plurality of p-type source/drain regions are sequentially formed. The n-type source/drain regions are respectively formed in the source/drain recesses 18 over the first region 1a, and the p-type source/drain regions are respectively formed in the source/drain recesses 18 over the second region 1b. In some embodiments, each of the n-type source/drain regions includes a plurality of base layers 24, a plurality of insulators 25, and a plurality of source/drain features 26. In some embodiments, each of the p-type source/drain regions includes a source/drain feature 27. In some embodiments, the n-type source/drain regions are formed before formation of the p-type source/drain regions.

In this step, firstly, the base layers 24 are respectively formed in the source/drain recesses 18 over the first region 1a. In some embodiments, the base layers 24 include or are made of, for example, but not limited to, silicon. Other suitable materials for forming the base layers 24 are within the contemplated scope of the present disclosure. In some embodiments, the base layers 24 may be formed by a suitable epitaxial growth process, for example, but not limited to, the SEG process. Other suitable processes for forming the base layers 24 are within the contemplated scope of the present disclosure.

Secondly, each of the insulators 25 is formed on a corresponding one of the base layers 24 in the source/drain recesses 18. In some embodiments, the insulators 25 include or are made of a dielectric material, for example, but not limited to, silicon nitride, silicon oxide, silicon oxynitride, or combinations thereof. Other suitable materials for forming the insulators 25 are within the contemplated scope of the present disclosure. In some embodiments, the insulators 25 are formed by a suitable deposition process, for example, but not limited to, CVD or ALD. Other suitable deposition processes for forming the insulators 25 are within the contemplated scope of the present disclosure.

Next, the source/drain features 26 are respectively formed on the insulators 25 and are respectively formed to fill the source/drain recesses 18 over the first region 1a (see FIG. 7). In some embodiments, each of the source/drain features 26 is formed by a suitable epitaxial growth process (for example, but not limited to, MBE) or an epitaxial deposition/partial etch process (e.g., a cyclic deposition-etch (CDE) process and/or the SEG process). Other suitable processes for forming the source/drain features 26 are within the contemplated scope of the present disclosure. In some embodiments, the source/drain features 26 may include a single epitaxial layer or multiple epitaxy layers having different materials and/or different dopant concentrations. In some embodiments, the source/drain features 26 include at least two epitaxy layers containing the same semiconductor materials with different dopant concentrations. In this case, each of the source/drain features 26 includes a plurality of seed portions 261 and an epitaxial layer 262. Each of the seed portions 261 is disposed on a side of a corresponding one of the channel features 122. In some embodiments, each of the seed portions 261 includes or is made of, for example, but not limited to, silicon or silicon doped with an n-type dopant (for example, but not limited to, phosphorus, arsenic, or a combination thereof). In some embodiments, each of the seed portions 261 includes or is made of, for example, but not limited to, silicon, silicon phosphide, silicon arsenic, or combinations thereof. In some embodiments, the epitaxial layer 262 includes or is made of, for example, but not limited to, silicon phosphide, silicon arsenic, or a combination thereof. Other suitable materials for forming each of the seed portions 261 and the epitaxial layer 262 are within the contemplated scope of the present disclosure. In some embodiments, a concentration of the n-type dopant (for example, but not limited to, phosphorus, arsenic, or a combination thereof) in the epitaxial layer 262 is greater than that of the n-type dopant in the seed portions 261 if the seed portions 261 contain the n-type dopant. In some embodiments, each of the source/drain features 26 may have an n-type conductivity, and may function as a source/drain of an n-type FET (n-FET).

It is noted that before formation of the n-type source/drain regions, the structure over the second region 1b is covered by a mask layer (e.g., a photoresist layer). After the formation of the n-type source/drain regions, the mask layer is removed.

Thereafter, the source/drain features 27 are respectively formed to fill the source/drain recesses 18 over the second region 1b. In some embodiments, each of the source/drain features 27 is formed by a suitable epitaxial growth process (for example, but not limited to, MBE) or an epitaxial deposition/partial etch process (e.g., the CDE process and/or the SEG process). Other suitable processes for forming the source/drain features 27 are within the contemplated scope of the present disclosure. In some embodiments, the source/drain features 27 may include a single epitaxial layer or multiple epitaxy layers having different materials and/or different dopant concentrations. In some embodiments, the source/drain features 27 include at least two epitaxy layers containing the same semiconductor materials with different dopant concentrations. In this case, each of the source/drain features 27 may include a seed layer 271, a first epitaxial layer 272, and a second epitaxial layer 273 that are sequentially disposed in a corresponding one of the source/drain recesses 18 over the second region 1b (see FIG. 7), where the seed layer 271 covers the first epitaxial layer 272 and the first epitaxial layer 272 covers the second epitaxial layer 273. In some embodiments, the seed layer 271 includes or is made of, for example, but not limited to, silicon or silicon germanium, which is undoped or doped with a p-type dopant (for example, but not limited to, boron, gallium, or a combination thereof). Other suitable materials for forming the seed layer 271 are within the contemplated scope of the present disclosure. In some embodiments, each of the first epitaxial layer 272 and the second epitaxial layer 273 includes or is made of, for example, but not limited to, silicon or silicon germanium which is doped with the p-type dopant (for example, but not limited to, boron, gallium, or a combination thereof). Other suitable materials for forming each of the first epitaxial layer 272 and the second epitaxial layer 273 are within the contemplated scope of the present disclosure. The source/drain recesses 18 over the second region 1b are defined by the sacrificial features 121, the channel features 122, and the protrusions 112, and in addition, the sacrificial features 121, the channel features 122, and the protrusions 112 include or are made of semiconductor materials as described above. Therefore, the seed layer 271 of each of the source/drain features 27 is formed as a continuous layer, which covers lateral surfaces of corresponding ones of the sacrificial features 121 and corresponding ones of the channel features 122, and covers a portion of a corresponding one of the protrusions 112. In some embodiments, the seed layer 271 may have a thickness ranging from about 0.5 nm to about 20 nm. If the thickness of the seed layer 271 is greater than 20 nm, formation of the first epitaxial layer 272 and the second epitaxial layer 273 may be adversely affected. In some embodiments, the dopant concentration of the first epitaxial layer 272 is greater than that of the seed layer 271 if the seed layer 271 contains the p-type dopant, and the dopant concentration of the second epitaxial layer 273 is greater than that of the first epitaxial layer 272. In some embodiments, each of the source/drain features 27 interfaces a sidewall of each of corresponding ones of the channel features 122. In some embodiments, the seed layer 271 of each of the source/drain features 27 is adjacent to the sidewall of each of corresponding ones of the channel features 122, and the first epitaxial layer 272 of the each of the source/drain features 27 is away from the sidewall of each of corresponding ones of the channel features 122. In some embodiments, each of the source/drain features 27 may have a p-type conductivity, and may function as a source/drain of a p-type FET (p-FET).

It is noted that after the formation of the n-type source/drain regions and before formation of the p-type source/drain regions, the structure over the first region 1a is covered by a mask layer (e.g., a photoresist layer). After the formation of the p-type source/drain regions, the mask layer is removed.

Since the upper portions of the protrusions 151 are also patterned and recessed during forming the source/drain recesses 18, each of the n-type source/drain regions and the p-type source/drain regions is partially embedded in a corresponding one of the protrusions 151.

In some embodiments, in step S07, formation of the p-type source/drain regions may be performed before formation of the n-type source/drain regions. In some embodiments, each of the n-type source/drain regions and the p-type source/drain regions extends into a corresponding one of protrusions 112 (formed from the semiconductor structure 1). In some embodiments, a thickness of each of the n-type source/drain regions is different from a width of the each of the n-type source/drain regions in a cross-sectional view. In some embodiments, a thickness of each of the p-type source/drain regions is different from a width of the each of the p-type source/drain regions in a cross-sectional view.

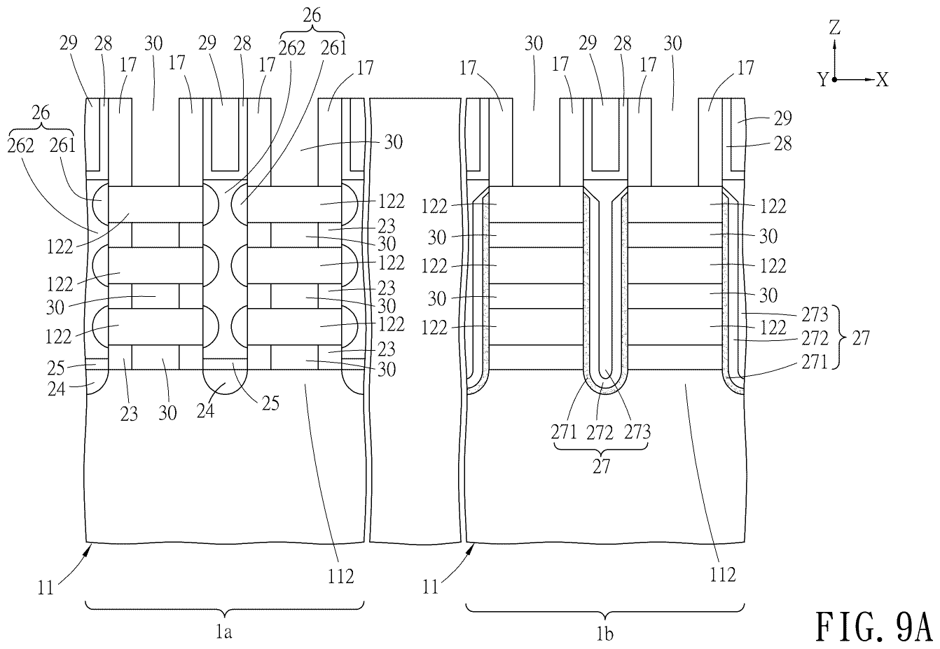

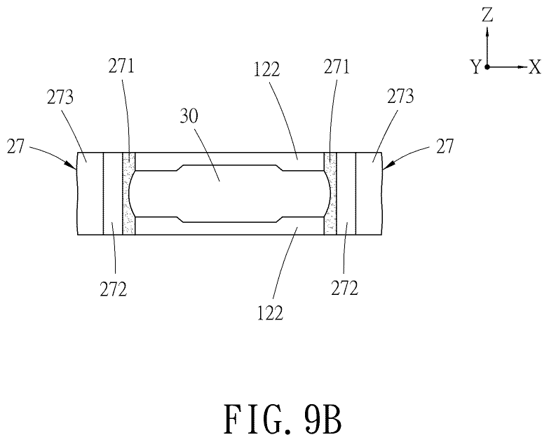

Referring to FIG. 1B and the examples illustrated in FIGS. 9A and 9B, the method 100A then proceeds to step S08, where a plurality of contact etch stop layers (CESLs) 28 and a plurality of interlayer dielectrics (ILDs) 29 are formed, followed by removing the dummy structures 16, the interposers 22, and the sacrificial features 121. FIG. 9B is a partially enlarged view of the structure over the second region 1b shown in FIG. 9A.

In this step, a first dielectric material layer (not shown) for forming the CESLs 28 is firstly formed on the structure shown in FIG. 8. In some embodiments, the first dielectric material layer includes or is made of, for example, but not limited to, silicon nitride, carbon-doped silicon nitride, or a combination thereof. Other suitable materials for forming the first dielectric material layer are within the contemplated scope of the present disclosure. In some embodiments, the first dielectric material layer is formed by a suitable deposition process, for example, but not limited to, ALD. Other suitable deposition processes for forming the first dielectric material layer are within the contemplated scope of the present disclosure.

Secondly, a second dielectric material layer (not shown) for forming the ILDs 29 is formed on the structure obtained after formation of the first dielectric material layer. In some embodiments, the second dielectric material layer includes or is made of, for example, but not limited to, silicon oxide, silicon nitride, silicon oxynitride, other low-k dielectric materials, or combinations thereof. Other suitable materials for forming the second dielectric material layer are within the contemplated scope of the present disclosure. In some embodiments, the second dielectric material layer is formed by a suitable deposition process, for example, but not limited to, CVD. Other suitable deposition processes for forming the second dielectric material layer are within the contemplated scope of the present disclosure.

Next, an excess portion of each of the first dielectric material layer and the second dielectric material layer, and the masks (respectively disposed on the dummy gates 162) are removed by a suitable planarization process (e.g., chemical mechanical polishing (CMP) until the dummy gates 162 are exposed, thereby obtaining the CESLs 28 and the ILDs 29.

In some embodiments, each of the n-type source/drain regions and the p-type source/drain regions is formed beneath a corresponding one of the CESLs 28 and a corresponding one of the ILDs 29.

Thereafter, the dummy structures 16 (i.e., the dummy dielectrics 161 and the dummy gates 162), the interposers 22 and the sacrificial features 121 are sequentially and separately removed by a plurality of etching processes, so as to form a plurality of cavities 30. In some embodiments, each of the etching processes may be, a dry etching process or a wet etching process. Other suitable etching processes are within the contemplated scope of the present disclosure.

As shown in FIG. 9B, a height (i.e., a size in the Z direction) of a center portion of each of the cavities 30 formed between corresponding two adjacent ones of the source/drain features 27 is greater than that of each of two opposite side portions of the each of the cavities 30. In some embodiments, the seed layer 271 is recessed by the two opposite side portions of each of the cavities 30.

Referring to FIG. 1B and the example illustrated in FIGS. 10A to 10C, the method 100A then proceeds to step S09, where a plurality of inner spacers 31, a plurality of interfacial layers 32, and a plurality of metal gates 33 are sequentially formed. Each of the metal gates 33 includes a gate dielectric layer 331 and a gate structure 332 (i.e., a plurality of the gate dielectric layers 331 and a plurality of the gate structures 332 are formed in this step).

In this step, as shown in FIG. 10B, a dielectric material layer 31′ for forming the inner spacers 31 is firstly formed to fill the cavities 30 of the structures over the second region 1b (see FIGS. 9A and 9B). In some embodiments, the dielectric material layer 31′ includes or is made of an oxide-based material (for example, but not limited to, silicon oxide) or a low-k dielectric material. Other suitable materials for forming the dielectric material layer 31′ are within the contemplated scope of the present disclosure. In some embodiments, the dielectric material layer 31′ is formed by a suitable deposition process, for example, but not limited to, plasma-enhanced ALD or thermal ALD. Other suitable deposition processes for forming the dielectric material layer 31′ are within the contemplated scope of the present disclosure. In some embodiments, the dielectric material layer 31′ is formed with seams 31a due to non-merging of a portion of the dielectric material layer 31′ disposed in the center portion of each of the cavities 30. One of the seams 31a is shown in FIG. 10B. It is noted that before formation of the dielectric material layer 31′, the structures over the first region 1a may be covered by a mask layer (e.g., a photoresist layer), and after the formation of the dielectric material layer 31′, the mask layer is removed.

Secondly, as shown in FIG. 10C, a portion of the dielectric material layer 31′ is removed by a suitable etching process, for example, but not limited to, a dry etching process, a wet etching process, or a combination thereof. The etching process is performed by introducing an etchant into the seams 31a to etch away the portion of the dielectric material layer 31′ adjacent to the seams 31a, so that a size of each of the seams 31a may be increased, and so that a plurality of pairs of the inner spacers 31 (i.e., remaining portions of the dielectric material layer 31′) are formed. Each of the seams 31a with an increased size may be referred to as a hole 31a (i.e., a plurality of the holes 31a are formed). Two of the inner spacers 31 in each pair are separated by a corresponding one of the holes 31a.

Next, the interfacial layers 32 are respectively formed around the channel features 122 and on portions of the protrusions 112. In some embodiments, the interfacial layers 32 include or are made of a dielectric material, for example, but not limited to, silicon oxide. Other suitable materials for forming the interfacial layers 32 are within the contemplated scope of the present disclosure. In some embodiments, the interfacial layers 32 are formed by a suitable deposition process, for example, but not limited to, CVD or ALD. Other suitable deposition processes for forming the interfacial layers 32 are within the contemplated scope of the present disclosure.

Thereafter, the gate dielectric layers 331 are formed in the cavities 30 and the holes 31a. In some embodiments, the gate dielectric layers 331 include or are made of a high-k material, for example, but not limited to, hafnium oxide, zirconium oxide, titanium oxide, yttrium oxide, magnesium oxide, calcium oxide, zirconium silicate, aluminum oxide, or scandium oxide. Other suitable materials for forming the gate dielectric layers 331 are within the contemplated scope of the present disclosure. The gate dielectric layers 331 have a dielectric constant (k value) that is higher than a dielectric constant of each of the gate spacers 17, the CESLs 28, and the ILDs 29. A thickness of each of the gate dielectric layers 331 is less than a thickness of each of the gate spacers 17. In some embodiments, the gate dielectric layers 331 are formed by a suitable deposition process, for example, but not limited to, CVD or ALD. Other suitable deposition processes for forming the gate dielectric layers 331 are within the contemplated scope of the present disclosure. In some embodiments, a thickness of each of the gate spacers 17 is greater than that of a corresponding one of the gate dielectric layers 331.

Afterwards, the gate structures 332 are formed to fill the cavities 30 and the holes 31a. In some embodiments, the gate structures 332 include or are made of, for example, but not limited to, aluminum, copper, tungsten, cobalt, ruthenium, titanium, tantalum, molybdenum, nickel, platinum, titanium nitride, tantalum nitride, or combinations thereof. Other suitable materials for forming the gate structures 332 are within the contemplated scope of the present disclosure. In some embodiments, the gate structures 332 are formed by a suitable deposition process, for example, but not limited to, CVD. Other suitable deposition processes for forming the gate structures 332 are within the contemplated scope of the present disclosure.

Then, a planarization process (e.g., CMP or other suitable planarization processes) is performed to remove an excess portion of each of the gate dielectric layers 331 and the gate structures 332, thereby obtaining the metal gates 33.

In some embodiments, a portion of each of the CESLs 28 extends along a sidewall of a corresponding one of the gate spacers 17, such that the corresponding one of the gate spacers 17 is between a corresponding one of the metal gate 33 and the portion of each of the CESLs 28.

After step S09, the first semiconductor device 200A and the second semiconductor device 200B are obtained. In some embodiments, each of the first semiconductor device 200A and the second semiconductor device 200B is a nanosheet FET device. In some embodiments, the first semiconductor device 200A serves as an n-type nanosheet FET device, and the second semiconductor device 200B serves as a p-type nanosheet FET device.

In some embodiments, the first semiconductor device 200A includes a plurality of transistor structures, and each of the transistor structures includes two corresponding ones of the source/drain features 26, corresponding ones of the channel features 122, corresponding ones of the inner spacers 23, corresponding ones of the interfacial layers 32, and a corresponding one of the metal gates 33.

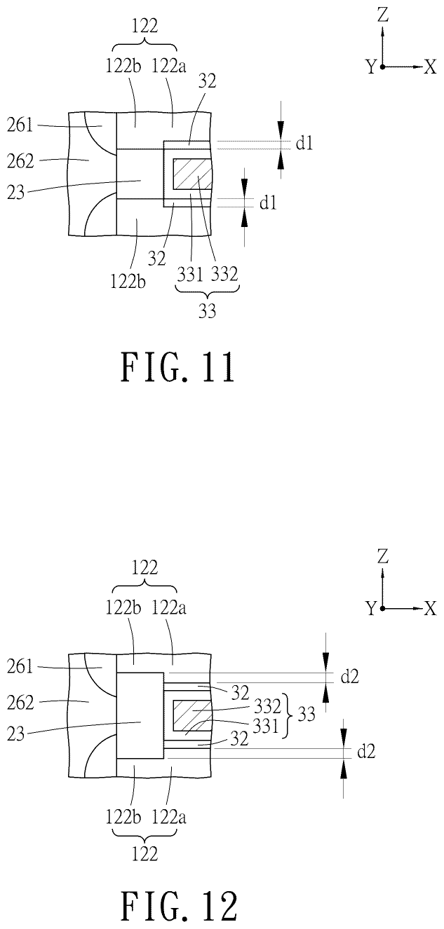

FIG. 11 is a partially enlarged view of a transistor structure of the first semiconductor device 200A shown in FIG. 10A. As shown in FIG. 11, each of the channel features 122 includes a central portion 122a, and two side portions 122b opposite to each other with respect to the central portion 122a and connected to the central portion 122a. One of the two side portions 122b is shown in FIG. 11. A thickness of the central portion 122a is less than a thickness of each of the two side portions 122b. Each of the inner spacers 23 has a first interface with a corresponding one of the two side portions 122b of a corresponding one of the channel features 122, and the central portion 122a of the corresponding one of the channel features 122 has a second interface with a corresponding one of the interfacial layers 32. A minimum distance (d1) in the Z direction between the first interface and the second interface ranges from about 0 nm to about 1.5 nm.

FIG. 12 (which is similar to FIG. 11) illustrates a transistor structure of the first semiconductor device 200A in accordance with some alternative embodiments. In the transistor structure shown in FIG. 12, the thickness of the central portion 122a is greater than the thickness of each of the two side portions 122b. A minimum distance (d2) between the first interface and the second interface ranges from about 0 nm to about 1.5 nm.

Referring to FIG. 10A, in some embodiments, the second semiconductor device 200B includes a plurality of transistor structures, and each of the transistor structures includes two corresponding ones of the source/drain features 27, corresponding ones of the channel features 122, corresponding ones of the inner spacers 31, corresponding ones of the interfacial layers 32, and a corresponding one of the metal gates 33.

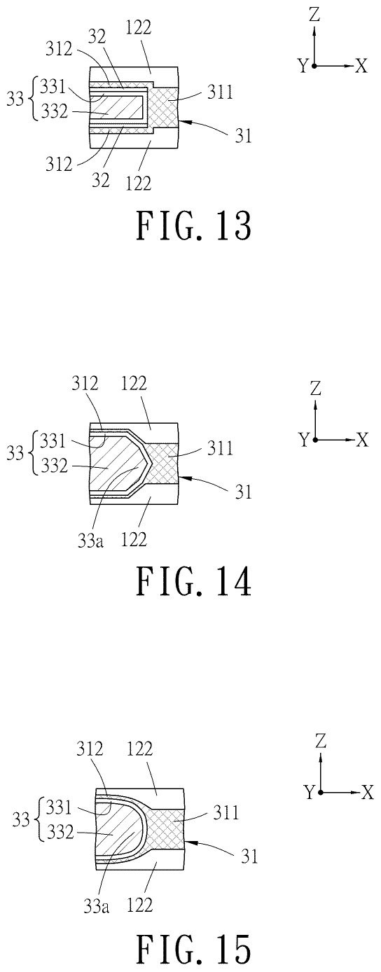

FIGS. 13 to 15 illustrate different configurations of the inner spacers 31 and the metal gates 33 of the transistor structures of the second semiconductor device 200B. One of the inner spacers 31 and one of the metal gates 33 are shown in each of FIGS. 13 to 15.

As shown in FIG. 13, in some embodiments, each of the metal gates 33 includes plurality of lower metal gate portions, each of which has a cross section of a rectangular shape. Each of the inner spacers 31 (i.e., the remaining portions of the dielectric material layer 31′) includes two side portions 311 and two interconnecting portions 312 connected between the two side portions 311. One of the two side portions 311 is shown in FIG. 13. Each of the interconnecting portions 312 of each of the inner spacers 31 is disposed between a corresponding one of the interfacial layers 32 and a corresponding one of the chancel features 122.

As shown in FIG. 14, in some embodiments, each of the lower metal gate portions of each of the metal gates 33 has two opposite side portions 33a with a cross section of a polygon shape. One of the two opposite side portions 33a is shown in FIG. 14. Similarly, each of the interconnecting portions 312 of each of the inner spacers 31 is disposed between a corresponding one of the interfacial layers 32 (not shown in FIG. 14) and a corresponding one of the chancel features 122.

As shown in FIG. 15, in some embodiments, each of the two opposite side portions 33a of each of the lower metal gate portions of each of the metal gates 33 has a cross section like a semi-circular shape. Similarly, each of the interconnecting portions 312 of each of the inner spacers 31 is disposed between a corresponding one of the interfacial layers 32 (not shown in FIG. 15) and a corresponding one of the chancel features 122.

In some embodiments, the second semiconductor device 200B is a p-type nanosheet FET device, and the channel features 122 are subjected to a compressive strain ranging from about 0 Gpa to about 2 Gpa.

In this disclosure, during formation of a p-type semiconductor device, a plurality of inner spacers are formed after formation of a plurality of source/drain features, so that the structural uniformity of each of the source/drain features can be enhanced by formation of a continuous seed layer of each of the source/drain features, which improves the device performance of the p-type semiconductor device (e.g., a drain current increasing by about 2% to about 9%). In addition, during formation of an n-type semiconductor device, by replacing a plurality of sacrificial features with a plurality of dielectric interposers, n-type dopants in a plurality of source/drain features of the n-type semiconductor device may not easily diffuse into a plurality of channel features of the n-type semiconductor device, thereby avoiding degradation to electrical performance of the n-type semiconductor device.

In accordance with some embodiments of the present disclosure, a method for manufacturing a semiconductor device includes: forming a first base semiconductor structure over a substrate, the first base semiconductor structure including a first stack portion and a second stack portion spaced apart from each other by a first recess, each of the first stack portion and the second stack portion including a plurality of first sacrificial features and a plurality of first channel features alternately stacked over each other; replacing the plurality of first sacrificial features with a plurality of dielectric interposers; and forming a first source/drain region in the first recess, the first source/drain region extending into the first base semiconductor structure, a thickness of the first source/drain region being different from a width of the first source/drain region in a cross-sectional view, the first source/drain region including a first source/drain feature having an n-type conductivity, the first source/drain feature including a plurality of seeding portions and an n-type epitaxial layer covering the plurality of seeding portions, the plurality of seeding portions containing a first semiconductor material, the n-type epitaxial layer containing the first semiconductor material and an n-type dopant.

In accordance with some embodiments of the present disclosure, the method for manufacturing the semiconductor device further includes, before formation of the first source/drain region, forming a plurality of inner spacers. Each of the plurality of dielectric interposers is laterally covered by two corresponding ones of the plurality of inner spacers.

In accordance with some embodiments of the present disclosure, each of the plurality of dielectric interposers is spaced apart from the n-type epitaxial layer by a corresponding one of the plurality of inner spacers.

In accordance with some embodiments of the present disclosure, the method for manufacturing the semiconductor device further includes, after formation of the first source/drain region, removing the plurality of dielectric interposers so as to form a plurality of cavities. Each of the plurality of cavities is disposed between two corresponding ones of the plurality of inner spacers.

In accordance with some embodiments of the present disclosure, the method for manufacturing the semiconductor device further includes: forming a second base semiconductor structure on the substrate, the second base semiconductor structure being spaced apart from the first base semiconductor structure, and including a third stack portion and a fourth stack portion spaced apart from each other by a second recess, each of the third stack portion and the fourth stack portion including a plurality of second sacrificial features and a plurality of second channel features alternately stacked over each other; and forming a second source/drain region in the second recess, the second source/drain region including a second source/drain feature having a p-type conductivity, the second source/drain feature including a seed layer, which is formed as a continuous layer covering lateral surfaces of the plurality of second sacrificial features and the plurality of second channel features.

In accordance with some embodiments of the present disclosure, the second source/drain feature further includes a first epitaxial layer and a second epitaxial layer. Each of the first epitaxial layer and the second epitaxial layer includes a p-type dopant. A concentration of the p-type dopant in the first epitaxial layer is different from a concentration of the p-type dopant in the second epitaxial layer. The first epitaxial layer is covered by the seed layer. The second epitaxial layer is covered by the first epitaxial layer.

In accordance with some embodiments of the present disclosure, replacement of the plurality of first sacrificial features with the plurality of dielectric interposers includes removing the plurality of first sacrificial features to form a plurality of spaces, and forming the plurality of dielectric interposers in the plurality of spaces, respectively.

In accordance with some embodiments of the present disclosure, the method for manufacturing the semiconductor device further includes before removal of the plurality of first sacrificial features, masking the second base semiconductor structure, and after formation of the plurality of dielectric interposers, unmasking the second base semiconductor structure.

In accordance with some embodiments of the present disclosure, masking the second base semiconductor structure includes: forming a mask layer to cover the first base semiconductor structure and the second base semiconductor structure; forming a polymeric material layer on the mask layer; removing a portion of the polymeric material layer and a portion of the mask layer covering the first base semiconductor structure; and removing a remaining portion of the polymeric material layer covering the second base semiconductor structure.

In accordance with some embodiments of the present disclosure, each of the plurality of seeding portions further contains the n-type dopant, and a concentration of the n-type dopant in the n-type epitaxial layer is greater than a concentration of the n-type dopant in each of the plurality of seeding portions.

In accordance with some embodiments of the present disclosure, a method for manufacturing a semiconductor device includes: forming a base semiconductor structure over a substrate that includes a protrusion; forming a recess that recesses the protrusion of the substrate and that penetrates the base semiconductor structure so that the base semiconductor structure is formed with a first stack portion and a second stack portion spaced apart from each other by the recess, each of the first stack portion and the second stack portion including a plurality of sacrificial features and a plurality of channel features alternately stacked over each other; and forming a source/drain feature in the recess, the source/drain feature interfacing a sidewall of each of the plurality of channel features, a thickness of the source/drain feature being different from a width of the source/drain feature in a cross-sectional view, the source/drain feature having a p-type conductivity, being doped with a dopant, and including a seed layer adjacent the sidewall of the each of the plurality of channel features, and a p-type epitaxial layer away from the sidewall of the each of the plurality of channel features and covered by the seed layer, the seed layer being formed as a continuous layer covering lateral surfaces of the plurality of sacrificial features and the plurality of channel features.

In accordance with some embodiments of the present disclosure, the method for manufacturing the semiconductor device further includes, after formation of the source/drain feature, removing the plurality of sacrificial features of each of the first stack portion and the second stack portion to form a plurality of cavities alternated with the plurality of channel features of the each of the first stack portion and the second stack portion; forming a dielectric material layer to fill the plurality of cavities; removing portions of the dielectric material layer to form a plurality of inner spacers and a plurality of holes, one of the plurality of inner spacers and a corresponding one of the plurality of holes being disposed between two corresponding ones of the plurality of channel features; and forming a first metal gate and a second metal gate to fill the plurality of holes.

In accordance with some embodiments of the present disclosure, each of the plurality of cavities includes a center portion and two opposite side portions, a height of the center portion being greater than a height of each of the two opposite side portions.

In accordance with some embodiments of the present disclosure, the seed layer is recessed by a corresponding one of the two opposite side portions of each of the plurality of cavities.

In accordance with some embodiments of the present disclosure, each of the plurality of inner spacers is formed to include two side portions respectively in the two opposite side portions of each of the plurality of cavities, and two interconnecting portions connected between the two side portions.

In accordance with some embodiments of the present disclosure, a semiconductor device includes a substrate, a plurality of first channel features, a plurality of second channel features, a first metal gate, a second metal gate, a pair of first gate spacers, a pair of second gate spacers, a source/drain region, an etch stop layer, and an interlayer dielectric. The substrate includes a protrusion. The plurality of first channel features and the plurality of second channel features are disposed on the protrusion of the substrate. The first metal gate is disposed to surround the plurality of first channel features and includes a first gate dielectric layer. The second metal gate is disposed to surround the plurality of second channel features and includes a second gate dielectric layer. The pair of first gate spacers laterally covers the first metal gate. A thickness of the pair of first gate spacers is greater than a thickness of the the first gate dielectric layer. The pair of second gate spacers laterally covers the second metal gate. A thickness of the second gate dielectric layer is less than a thickness of the pair of second gate spacers. The source/drain region is disposed between the plurality of first channel features and the plurality of second channel features, and includes a source/drain feature. The source/drain feature has a p-type conductivity and includes a seed layer. The seed layer is formed as a continuous layer covering lateral surfaces of the plurality of first channel features and the plurality of second channel features. The etch stop layer is disposed over the source/drain region. The interlayer dielectric is disposed over the etch stop layer. A portion of the etch stop layer extends along a sidewall of each of the pair of first gate spacers and the pair of second gate spacers, such that each of the pair of first gate spacers is between the first metal gate and the etch stop layer, and each of the pair of second gate spacers is between the second metal gate and the etch stop layer.

In accordance with some embodiments of the present disclosure, the seed layer has a thickness ranging from about 0.5 nm to about 20 nm.

In accordance with some embodiments of the present disclosure, the semiconductor device further includes a plurality of inner spacers. Each of the plurality of inner spacers includes two side portions and two interconnecting portions connected between the two side portions. The two interconnecting portions of the each of the plurality of inner spacers are respectively disposed at two opposite sides of a lower metal gate portion of a corresponding one of the first metal gate and the second metal gate.

In accordance with some embodiments of the present disclosure, the lower metal gate portion has two opposite side portions, and each of the two opposite side portions has a cross section of a polygon shape.

In accordance with some embodiments of the present disclosure, the lower metal gate portion has two opposite side portions, and each of the two opposite side portions has a cross section of a semi-circular shape.

In accordance with some embodiments of the present disclosure, a method for manufacturing a semiconductor device includes: forming a first base semiconductor structure and a second base semiconductor structure on a protrusion of a substrate, the first base semiconductor structure and the second base semiconductor structure being spaced apart from each other; forming a first recess and a second recess that recess the protrusion and that respectively penetrate the first base semiconductor structure and the second base semiconductor structure, so that the first base semiconductor structure is formed with a first stack portion and a second stack portion spaced apart from each other by the first recess, and the second base semiconductor structure is formed with a third stack portion and a fourth stack portion spaced apart from each other by the second recess, each of the first stack portion, the second stack portion, the third stack portion and the fourth stack portion including a plurality of sacrificial features and a plurality of channel features alternately stacked over each other; forming a mask layer to cover the first base semiconductor structure and the second base semiconductor structure; forming a polymeric material layer on the mask layer; removing a portion of the polymeric material layer and a portion of the mask layer covering the first base semiconductor structure; removing the plurality of sacrificial features of each of the first stack portion and the second stack portion, so as to form a plurality of spaces; removing a remaining portion of the polymeric material layer covering a remaining portion of the mask layer that covers the second base semiconductor structure; forming a plurality of interposers to fill the plurality of spaces, respectively; removing the remaining portion of the mask layer that covers the second base semiconductor structure; forming a first source/drain region and a second source/drain feature region in the first recess and the second recess, respectively, the first source/drain region extending into the first base semiconductor structure, the second source/drain region extending into the second base semiconductor structure, the first source/drain region including a first source/drain feature having an n-type conductivity, and the first source/drain feature including a plurality of seeding portions and an epitaxial layer covering the plurality of seeding portions, the plurality of seeding portions including a semiconductor material, the epitaxial layer containing the semiconductor material and an n-type dopant, the second source/drain region including a second source/drain feature having a p-type conductivity; removing the plurality of interposers, so as to form a plurality of first cavities; removing the plurality of sacrificial features of each of the third stack portion and the fourth stack portion, so as to form a plurality of second cavities; forming a dielectric material layer to fill the plurality of second cavities; removing portions of the dielectric material layer, so as to form a plurality of inner spacers and a plurality of holes; and forming a plurality of metal gates to fill the plurality of first cavities and the plurality of holes.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor device, comprising:
forming a first base semiconductor structure over a substrate, the first base semiconductor structure including a first stack portion and a second stack portion spaced apart from each other by a first recess, each of the first stack portion and the second stack portion including a plurality of first sacrificial features and a plurality of first channel features alternately stacked over each other;
replacing the plurality of first sacrificial features with a plurality of dielectric interposers; and
forming a first source/drain region in the first recess, the first source/drain region extending into the first base semiconductor structure, a thickness of the first source/drain region being different from a width of the first source/drain region in a cross-sectional view, the first source/drain region including a first source/drain feature having an n-type conductivity, the first source/drain feature including a plurality of seeding portions and an n-type epitaxial layer covering the plurality of seeding portions, the plurality of seeding portions containing a first semiconductor material, the n-type epitaxial layer containing the first semiconductor material and an n-type dopant.

2. The method as claimed in claim 1, further comprising, before formation of the first source/drain region, forming a plurality of inner spacers, each of the plurality of dielectric interposers being laterally covered by two corresponding ones of the plurality of inner spacers.

3. The method as claimed in claim 2, wherein each of the plurality of dielectric interposers is spaced apart from the n-type epitaxial layer by a corresponding one of the plurality of inner spacers.

4. The method as claimed in claim 3, further comprising, after formation of the first source/drain region, removing the plurality of dielectric interposers so as to form a plurality of cavities, each of the plurality of cavities being disposed between two corresponding ones of the plurality of inner spacers.

5. The method as claimed in claim 2, further comprising forming a second base semiconductor structure on the substrate, the second base semiconductor structure being spaced apart from the first base semiconductor structure, and including a third stack portion and a fourth stack portion spaced apart from each other by a second recess, each of the third stack portion and the fourth stack portion including a plurality of second sacrificial features and a plurality of second channel features alternately stacked over each other; and
forming a second source/drain region in the second recess, the second source/drain region including a second source/drain feature having a p-type conductivity, the second source/drain feature including a seed layer, which is formed as a continuous layer covering lateral surfaces of the plurality of second sacrificial features and the plurality of second channel features.

6. The method as claimed in claim 5, wherein the second source/drain feature further includes a first epitaxial layer and a second epitaxial layer, each of which includes a p-type dopant, a concentration of the p-type dopant in the first epitaxial layer being different from a concentration of the p-type dopant in the second epitaxial layer, the first epitaxial layer being covered by the seed layer, the second epitaxial layer being covered by the first epitaxial layer.

7. The method as claimed in claim 1, wherein replacement of the plurality of first sacrificial features with the plurality of dielectric interposers includes:
removing the plurality of first sacrificial features to form a plurality of spaces; and
forming the plurality of dielectric interposers in the plurality of spaces, respectively.

8. The method as claimed in claim 7, further comprising:
before removal of the plurality of first sacrificial features, masking the second base semiconductor structure; and
after formation of the plurality of dielectric interposers, unmasking the second base semiconductor structure.

9. The method as claimed in claim 8, wherein masking the second base semiconductor structure includes:
forming a mask layer to cover the first base semiconductor structure and the second base semiconductor structure;
forming a polymeric material layer on the mask layer;
removing a portion of the polymeric material layer and a portion of the mask layer covering the first base semiconductor structure; and
removing a remaining portion of the polymeric material layer covering the second base semiconductor structure.

10. The method as claimed in claim 1, wherein each of the plurality of seeding portions further contains the n-type dopant, and a concentration of the n-type dopant in the n-type epitaxial layer is greater than a concentration of the n-type dopant in the each of the plurality of seeding portions.

11. A method for manufacturing a semiconductor device, comprising:
forming a base semiconductor structure over a substrate that includes a protrusion;
forming a recess that recesses the protrusion of the substrate and that penetrates the base semiconductor structure so that the base semiconductor structure is formed with a first stack portion and a second stack portion spaced apart from each other by the recess, each of the first stack portion and the second stack portion including a plurality of sacrificial features and a plurality of channel features alternately stacked over each other; and
forming a source/drain feature in the recess, the source/drain feature interfacing a sidewall of each of the plurality of channel features, a thickness of the source/drain feature being different from a width of the source/drain feature in a cross-sectional view, the source/drain feature having a p-type conductivity, being doped with a dopant, and including a seed layer adjacent the sidewall of the each of the plurality of channel features, and a p-type epitaxial layer away from the sidewall of the each of the plurality of channel features and covered by the seed layer, the seed layer being formed as a continuous layer covering lateral surfaces of the plurality of sacrificial features and the plurality of channel features.

12. The method as claimed in claim 11, further comprising, after formation of the source/drain feature:
removing the plurality of sacrificial features of each of the first stack portion and the second stack portion to form a plurality of cavities alternated with the plurality of channel features of the each of the first stack portion and the second stack portion;
forming a dielectric material layer to fill the plurality of cavities;
removing portions of the dielectric material layer to form a plurality of inner spacers and a plurality of holes, one of the plurality of inner spacers and a corresponding one of the plurality of holes being disposed between two corresponding ones of the plurality of channel features; and
forming a first metal gate and a second metal gate to fill the plurality of holes.

13. The method as claimed in claim 12, wherein each of the plurality of cavities includes a center portion and two opposite side portions, a height of the center portion being greater than a height of each of the two opposite side portions.

14. The method as claimed in claim 13, wherein the seed layer is recessed by a corresponding one of the two opposite side portions of each of the plurality of cavities.

15. The method as claimed in claim 13, wherein each of the plurality of inner spacers is formed to include two side portions respectively in the two opposite side portions of each of the plurality of cavities, and two interconnecting portions connected between the two side portions.

16. A semiconductor device, comprising:
a substrate including a protrusion;
a plurality of first channel features and a plurality of second channel features disposed on the protrusion of the substrate;
a first metal gate disposed to surround the plurality of first channel features and including a first gate dielectric layer;
a second metal gate disposed to surround the plurality of second channel features and including a second gate dielectric layer;
a pair of first gate spacers laterally covering the first metal gate, a thickness of the pair of first gate spacers being greater than a thickness of the first gate dielectric layer;
a pair of second gate spacers laterally covering the second metal gate, a thickness of the second gate dielectric layer being less than a thickness of the pair of second gate spacers;
a source/drain region disposed between the plurality of first channel features and the plurality of second channel features, and including a source/drain feature having a p-type conductivity, the source/drain feature including a seed layer, which is formed as a continuous layer covering lateral surfaces of the plurality of first channel features and the plurality of second channel features;
an etch stop layer disposed over the source/drain region; and
an interlayer dielectric disposed over the etch stop layer,
a portion of the etch stop layer extending along a sidewall of each of the pair of first gate spacers and the pair of second gate spacers, such that each of the pair of first gate spacers is between the first metal gate and the etch stop layer, and each of the pair of second gate spacers is between the second metal gate and the etch stop layer.

17. The semiconductor device as claimed in claim 16, wherein the seed layer has a thickness ranging from 0.5 nm to 20 nm.

18. The semiconductor device as claimed in claim 16, further comprising a plurality of inner spacers, each of the plurality of inner spacers including two side portions and two interconnecting portions connected between the two side portions, the two interconnecting portions of the each of the plurality of inner spacers being respectively disposed at two opposite sides of a lower metal gate portion of a corresponding one of the first metal gate and the second metal gate.

19. The semiconductor device as claimed in claim 18, wherein the lower metal gate portion has two opposite side portions, each of which has a cross section of a polygon shape.

20. The semiconductor device as claimed in claim 18, wherein the lower metal gate portion has two opposite side portions, each of which has a cross section of a semi-circular shape.
